(19) United States
(12) Patent Application Publication
(10) Pub. No.: US 2008/0290883 A1
(43) Pub. Date: Nov. 27, 2008

(54) Testboard with ZIF connectors, method of assembling, integrated circuit test system and test method introduced by the same

(75) Inventor: LIN YUAN-CHI, Hsin-Chu City (TW)

Correspondence Address: SINORICA, LLC, 528 FALLSGROVE DRIVE, ROCKVILLE, MD, 20850, US

(73) Assignee: King Yuan Electronics To., Ltd.

(21) Appl. No.: 11/889,397

(22) Filed: Aug. 13, 2007

(30) Foreign Application Priority Data
May 25, 2007 (CN) 096118656

(51) Int. Cl. G01R 31/02; H01R 13/62; H01R 43/00

(52) U.S. Cl. 324/755; 29/857; 324/757; 439/259; 439/65

(57) ABSTRACT

This invention discloses a test board with detachably adjustable ZIF connectors. The test board comprises a test substrate, a plurality of ZIF connectors and a plurality of detachably adjustable fastening means for assembling and disassembling the ZIF connectors on the test substrate. The test substrate has a first surface, a second surface and a plurality of first through-holes perpendicular to the first surface. Pairs of first electrical pads are provided on the first surface adjacent to both sides of first through-holes. A plurality of second electrical pads are provided on the second surface of the test substrate for electrically connecting the first electrical pads. The ZIF connectors are arranged on the first surface of the substrate. Each ZIF connector has a plurality of parallel second through-holes arranged from the top to the bottom of the connector and pairs of electrical terminals are disposed on the bottom of each ZIF connector for contacting the first electrical pads of the test substrate. The detachably adjustable fastening means are disposed through the first and second through-holes to assembling and disassembling the ZIF connectors on the first surface of the substrate.

### FIELD OF THE INVENTION

The present invention relates to a test board and a test system used in a Integrated Circuit (IC) device test, and more particularly, to a test board with ZIF connectors and an assembling method introduced by the same.

### BACKGROUND OF THE INVENTION

When general integrated circuit (IC) devices are performed to do final tests, electrical contacts or pins of the IC devices need to be pressed and contacted with pogo pins of sockets so as to transmit test signals through the pogo pins to a tester to verify the IC devices.

Refer to FIG. 1A. A schematic view of an IC device test system is illustrated. A control system 10 emits a test signal and passes it to a tester 12 as known by those skilled in the art. A motherboard 15 and ZIF (Zero Insertion Force) female plug connectors 17 are equipped on the tester 12. The ZIF female plug connectors 17 are connected with ZIF connectors 18 so as to transmit the test signal to the test board 19. U.S. Pat. Nos. 6,184,698, 6,398,570, 6,478,596 as well as Taiwan Patent No. TW475984 have disclosed a method for connecting the ZIF female plug connectors 17 with the ZIF connectors 18. A test board 19 is provided with probe pins 20 on its bottom for electrically connecting the ZIF connectors 18. A test system loads the IC device under test 21 onto a socket 22 so that the IC device 21 can be contacted with the probe pins 20 on the bottom of the test board 19 via the movement of the socket 22 to perform the test as well as to send the test signal back to the control system 10.

Refer to FIG. 1B. A conventional connection mode of the ZIF connector 18 and the test board 19 is shown. A rivet 201 directly passes through the ZIF connector 18 and the test board 19, thus the ZIF connector 18 is riveted on the upper surface of the test board 19. A plurality of golden fingers 202 are disposed on each of two sides of the ZIF connectors 18 so as to transmit test signals to the ZIF female plug connector 17. In addition, the golden fingers 202 are extended under the ZIF connector 18 and extended outwardly to form a radial shape so as to make contact with pads on the test board 19 (not shown) for receiving test signals. In the conventional rivet-connection mode, the swaging force needs to be precisely controlled in strength and direction when swaging the rivet 201. As a result, a certain gap A and a certain predetermined force can be maintained after all the golden fingers 202 have the contact with the pad on the test board 19, thereby the impedance match can be fixed to obtain the stable test signals. During the IC device testing process, the ZIF connectors 18 must be capable of sustaining the repeatedly plugged and unplugged operations from the female plug connector 17. After a while, the golden fingers 202 will be worn out so that it will change both the gap A and the predetermined force to cause bad connections between the pad portion of the test board 19 and the golden fingers 202, thereby the test result will be affected. Then, the test board will have to be replaced for maintenance.

Refer to FIG. 1C. A schematic view of another conventional ZIF connector structure from U.S. Pat. No. 6,642,729 is shown. Fixed pins (i.e. rivets) 1251 and 1253 are disposed under the ZIF connectors so that the ZIF connectors can be connected to the test board and affixed thereon.

It is to be noted that when the test board 19 performs the IC device test, if the abnormality occurs in the gap A or the predetermined force between some golden finger of the ZIF connectors 18 and the test board 19, the whole test board 19 has to be removed from the test system. The ZIF connector 18 needs to be replaced and the gap A and the predetermined force need to be re-adjusted. During the steps of replacing the ZIF connector 18, a rivet head needs to be peeled off by using a sharp knife so that the rivet can be removed; however, if force is carelessly applied, the ZIF connector 18 can be easily damaged, or worse, the test board 19 can be damaged. General speaking, the structure of the test board 19 is very complex and it is of multiple layers. The pitch between the pads thereon is very small and needs to be reworked at a semiconductor level so that the price is extremely expensive. The cost becomes very high due to replacing the whole test board 19, when damage is caused by adjusting or detaching a ZIF connector 18. Therefore, what is needed for industrial fields is to provide a simple and effective approach to connecting, replacing and adjusting the ZIF connectors and the test board.

### SUMMARY OF THE INVENTION

In order to solve the above mentioned problems, the present invention provides an IC device test system, a test board, and ZIF connectors used therein. The test board is equipped with replaceable and detachably adjustable ZIF connectors. The test board includes a test substrate, a plurality of ZIF connectors, and a plurality of detachably adjustable fastening means. The test substrate is provided with a plurality of first through-holes perpendicular to the first surface. Pairs of first electric contacts are provided on the first surface adjacent to both sides of first through-holes. The ZIF connectors are arranged on the surface of the test substrate and each ZIF connector has parallelly arranged second through-holes. The detachably adjustable fastening means are disposed through the first and second through-holes for assembling and disassembling the ZIF connectors on the surface of the test substrate.

Therefore, the object of the present invention is to provide a test board with a novel connection mode to the ZIF connector, whereby it is easy to maintain or replace a damaged ZIF connector located on the test board.

Another object of the present invention is to provide a test board that may appropriately adjust the contact force between the golden fingers of the ZIF connector and the pads on the test board so as to obtain stable test signals.

Yet another object of the present invention is to provide an assembling method for the test board so that the ZIF connector can be installed on the test board in an easier manner.

Yet another object of the present invention is to provide an assembling method for the test board so as to adjust the contact force between the ZIF connectors and the test board.

Yet another object of the present invention is to provide an IC device test system. The structure has a novel connection mode for the ZIF connector, so that the damaged ZIF connector on the test board can be easily maintained or replaced, and the contact force between the ZIF connector and the test board can be adjusted at the same time.

Yet another object of the present invention is to provide an IC device test system. The test board structure used in the IC device test system has a novel connection mode for the ZIF connector, so that the damaged ZIF connector on the test board can be easily maintained or replaced, and the contact force between the ZIF connector and the test board can be adjusted at the same time.

Yet another object of the present invention is to provide a IC device test method. The test board used in the IC device test method has a novel connection mode for the ZIF connector so that the damaged ZIF connector on the test board can be easily repaired or replaced and the contact force between the ZIF connector and the test board can be adjusted at the same time.

### BRIEF DESCRIPTION OF THE DRAWINGS

FIG. 1A is a schematic view of a conventional IC device test system;

FIG. 1B is a cross-sectional view of a conventional connection mode for a ZIF connector and a test board;

FIG. 1C is a three-dimensional view of a conventional ZIF connector and a fixed pin;

FIG. 2A is a cross-sectional view of a test board equipped with ZIF connectors in accordance with the first embodiment of the present invention;

FIG. 2B is a cross-sectional view of a fastening plate in accordance with the first embodiment of the present invention;

FIG. 2C is a cross-sectional view of the first embodiment further equipped with a first depressor in accordance with the present invention;

FIG. 2D is a cross-sectional view of the first embodiment further equipped with a second depressor in accordance with the present invention;

FIG. 2E is a schematic view of layouts of the ZIF connector in accordance with the present invention;

FIG. 3 is a schematic view of a test board equipped with a socket in accordance with the second embodiment of the present invention;

FIG. 4 is a flow chart showing an assembling method for a test board equipped with a ZIF connector in accordance with the third embodiment of the present invention;

FIG. 5 is a flow chart showing an assembling method for a test board with a ZIF connector and in accordance with the fourth embodiment of the present invention;

FIG. 6 is a schematic view of an IC device test system equipped with a test board in accordance with the fifth embodiment of the present invention; and

FIG. 7 is a flow chart showing an IC device test method in accordance with the sixth embodiment of the present invention.

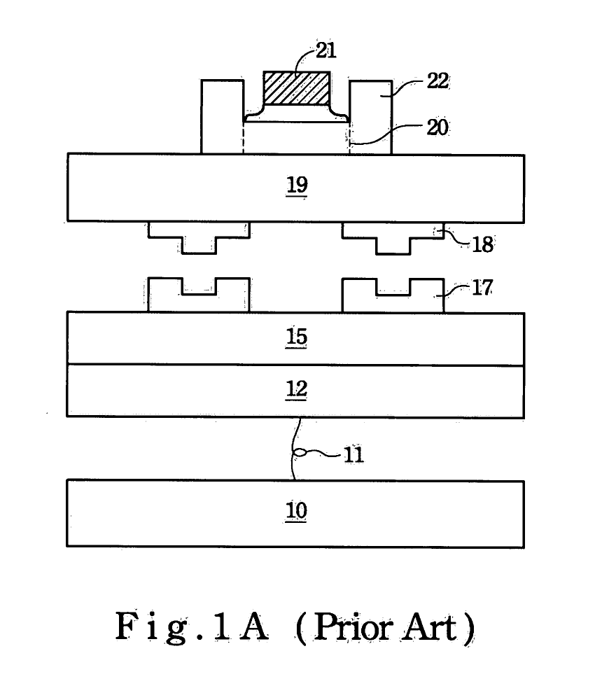

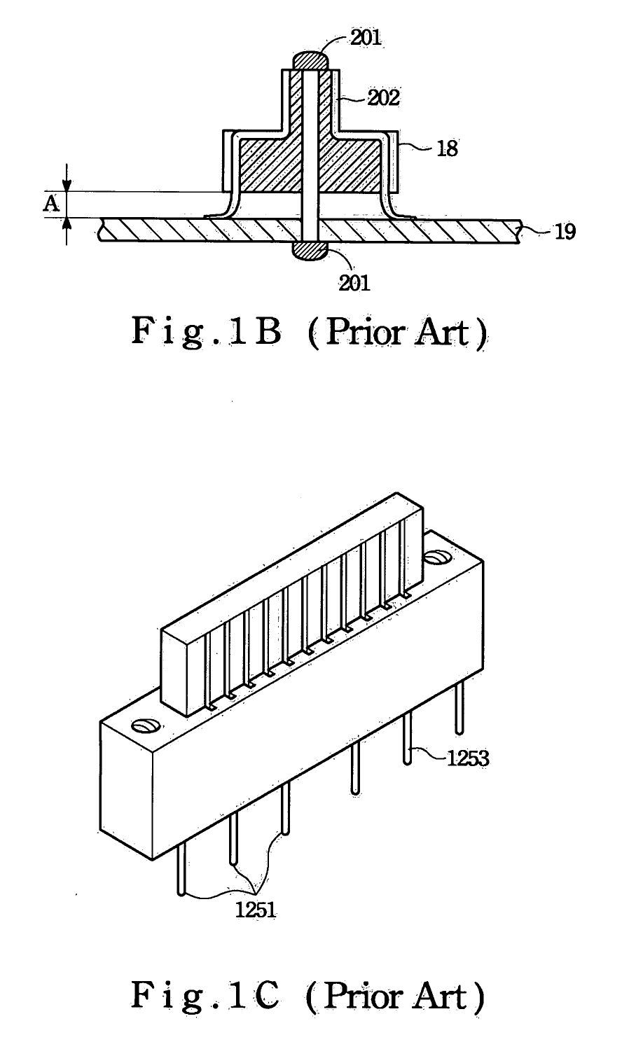

### DETAILED DESCRIPTION OF THE PREFERRED EMBODIMENTS

Since the present invention discloses a final test for an IC device in the semiconductor back-end processing, wherein the basic principles of the semiconductor manufacturing are well-known by those skilled in the art, the following description will omit the description of the principles. Moreover, the diagrams included in the following are not completely drawn according to the real size and are only used to demonstrate features related to the present invention.

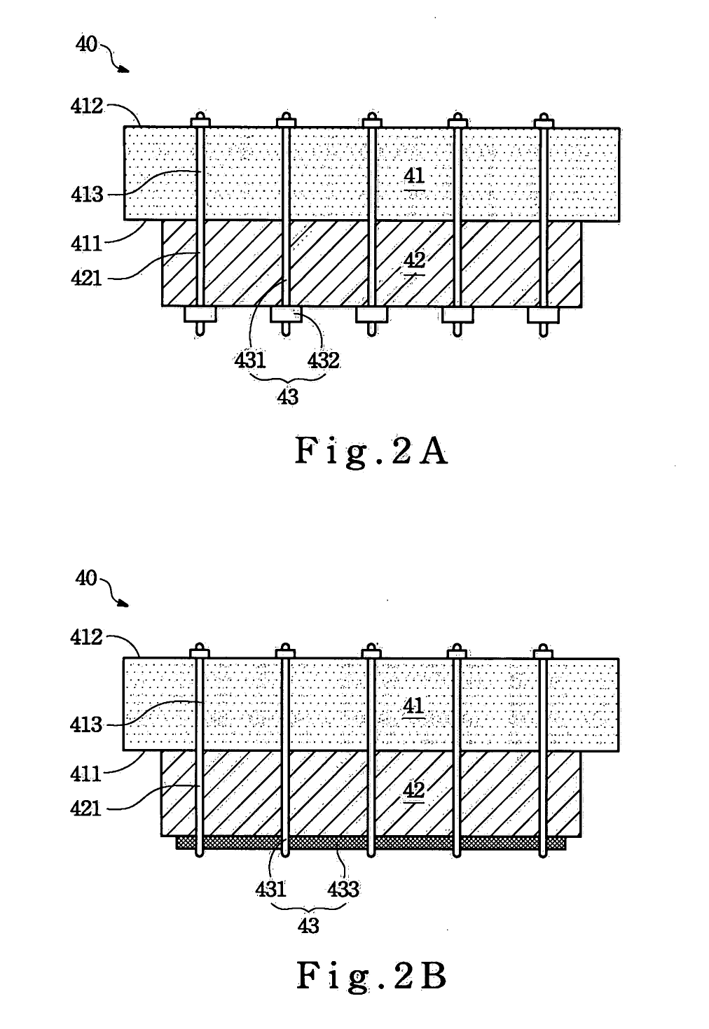

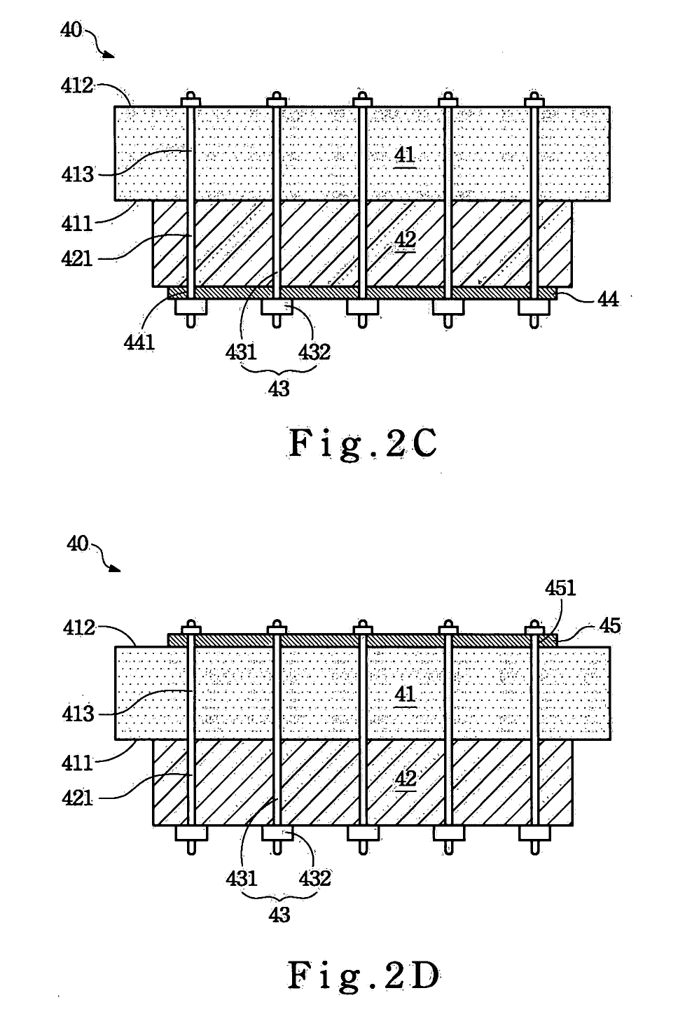

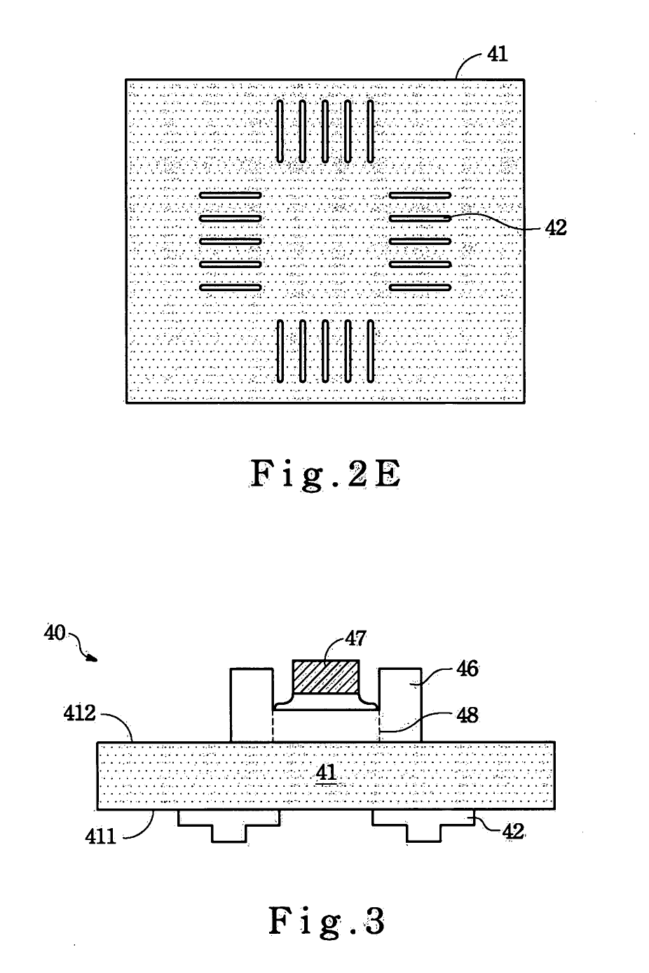

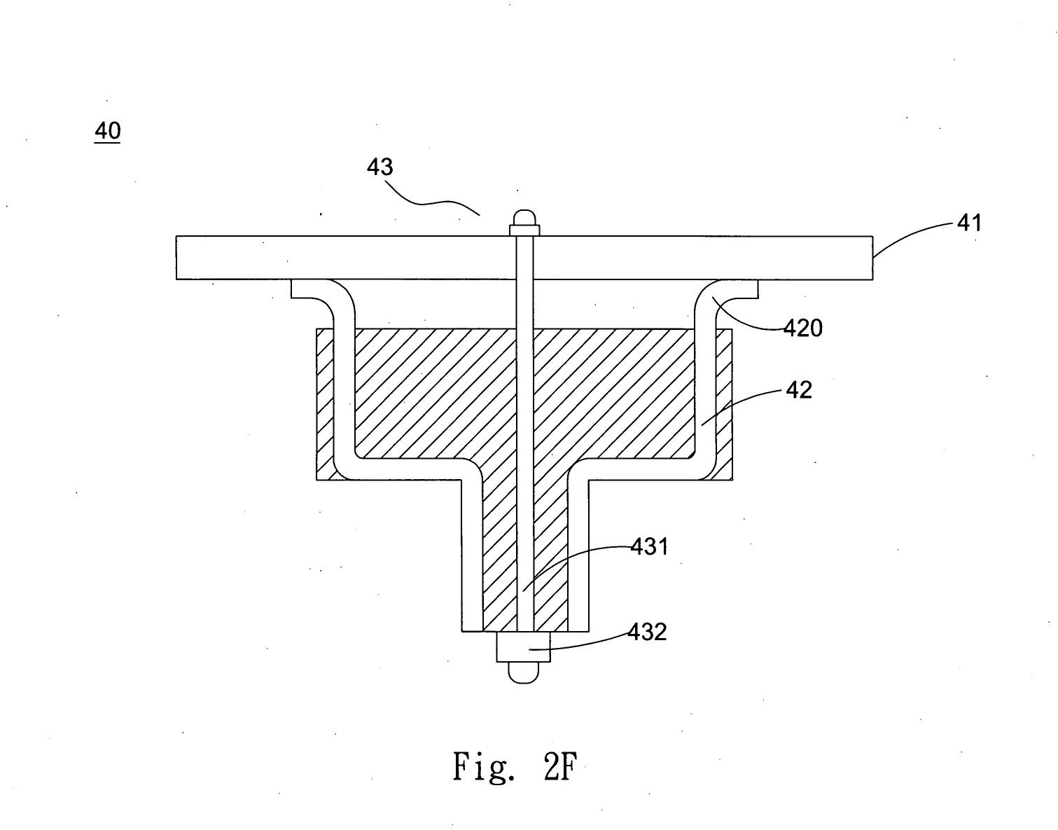

Refer to FIG. 2A. A test board with ZIF connectors is shown in accordance with the first preferable embodiment of the present invention. The test board 40 comprises a test substrate 41, a plurality of second electrical pads (not shown), a plurality of ZIF connectors 42 and a plurality of detachably adjustable fastening means 43, wherein a gap (not shown) exists between the test substrate 41 and the ZIF connector 42 for adjusting the contact force between the test substrate 41 and the ZIF connector 42 by means of the plurality of detached adjustable fastening means 43. The test substrate 41 has a first surface 411, a second surface 412, and a plurality of first through-holes 413 perpendicular to the first surface 411 and the second surface 412 of the test substrate 41. Pairs of first electric contacts (not shown) are provided on the first surface 411 adjacent to both sides of first through-holes 413. A plurality of electric contacts is arranged on the second surface 412 of the test substrate 41 and electrically contact with the first electric contacts. The plurality of ZIF connectors 42 are arranged on the first surface 411 of the test substrate 41, and each of the ZIF connector 42 has a plurality of parallelly arranged second through-holes 412 from the top to the bottom of the ZIF connector 42 and pairs of electric terminals (not shown) are disposed on the bottom of each ZIF connector 42 for contacting the first electric contacts (not shown) of the test substrate 41. The plurality of detachably adjustable fastening means 43 are disposed through the first through-holes 413 and second through-holes 421 to affix the ZIF connectors 42 on the first surface 411 of the test substrate 41.

In the above mentioned embodiment, the fastening means 43 are detachably adjustable, such as a combination of a bolt 431 and a nut 432. For the sake of convenient assembly, the bolt 431 may pass through the test substrate 41 and the ZIF connector 42 from the upside of the test substrate 41 to affix the nut 432 on the downside of the ZIF connector 42, as shown in FIG. 2A. Alternatively, the bolt 431 may pass through the ZIF connector 42 and the test substrate 41 from the downside of the ZIF connector 42 to affix the nut 432 on the upside of the ZIF connector 42 of the test substrate 41 (not shown). The number of the bolt 431 is not limited as long as the force for driving the ZIF connector 42 affixed to the test substrate 41 is strong enough to make a stable connection therein.

In the above mentioned embodiment, multiple nuts can be integrated into a fastening plate 433 with multiple holes, as shown in FIG. 2B. When assembled, the bolt 431 may pass through the test substrate 41 and the ZIF connector 42 from the upside of the test substrate 41 to affix the fastening plate 433 on the downside of the ZIF connector 42. Alternatively, the bolt 431 may pass through the ZIF connector 42 and the test substrate 41 from the downside of the ZIF connector 42 to affix the fastening plate 433 on the upside of the test substrate 41, wherein a gap (not shown) exists between the test substrate 41 and the ZIF connector 42 for adjusting contact force between the test substrate 41 and the ZIF connector 42 by means of the plurality of detached adjustable fastening means 43.

In the above mentioned embodiment, in order to enhance the fastening force to affix the ZIF connector 42 to the test substrate 41, the sealing gel or resin may be further provided in the cross locking portions of the fastening means 43 to decrease the loosening possibility of the fastening means 43 for connecting the ZIF connector 42 with the test substrate 41.

In the above mentioned embodiment, the first depressor 44 may be further provided on the top surface of the ZIF connectors 42, as shown in FIG. 2C. The first depressor 44 is provided with the third through-holes 441 located on the opposite side of the second through-holes 421 so that the fastening means 43 can pass therethrough for being affixed thereon. The function of the first depressor 44 is to scatter the pressure directly applied on the ZIF connectors 42 from the fastening means 43 as well as to prevent the fastening means 43 from scratching the surface of the ZIF connector 42. Besides, the gap (not shown) exists between the test substrate 41 and the ZIF connector 42 for adjusting contact force between the test substrate 41 and the ZIF connector 42 by means of the plurality of detached adjustable fastening means 43.

In the above mentioned embodiment, the second depressor 45 may be provided on the second surface 412 of the test substrate 41, as shown in FIG. 2D. The second depressor 45 is provided with the fourth through-holes 451 located on the opposite side of the first through-holes 413 of the test substrate 41 so that the fastening means 43 can pass therethrough for being affixed thereon. The function of the second depressor 45 is to scatter the pressure directly applied on the test substrate 41 from the fastening means 43 as well as to prevent the fastening means 43 from scratching the surface of the test substrate 41. And, a gap (not shown) exists between the test substrate 41 and the ZIF connector 42 for adjusting contact force between the test substrate 41 and the ZIF connector 42 by means of the plurality of detached adjustable fastening means 43.

The above mentioned first depressor 44 and second depressor 45 may be provided separately or together. The fastening means 43 may be a combination of a bolt 431 and a nut 432, or a combination of a bolt 431 and a fastening plate 433. When assembled, a bolt 431 may pass through the test substrate 41 and the ZIF connectors 42 from the topside of the test substrate 41 for being affixed on the downside of the ZIF connectors 42; alternatively, a bolt 431 may pass through the ZIF connectors 42 and the test substrate 41 from the downside of the ZIF connectors 42 for being affixed on the upside of the test substrate 41. In the above mentioned embodiment, the plurality of the ZIF connectors 42 are arranged in an array shape, as shown in FIG. 2E, in four sides of rectangular shape, in opposite sides shape, or in adjacent sides shape of the rectangular. And, a gap (not shown) exists between the test substrate 41 and the ZIF connector 42 for adjusting contact force between the test substrate 41 and the ZIF connector 42 by means of the plurality of detached adjustable fastening means 43.

Refer to FIG. 3. An IC device test system equipped with ZIF connectors is shown in accordance with the second preferable embodiment of the present invention. The test board 40 includes at least a test substrate 41, a plurality of ZIF connectors 42, at least a socket 46 and a plurality of detachably adjustable fastening means 43. Wherein, the socket 46 is affixed on the second surface 412 of said test board 41 for receiving an integrated circuit device under test 47, and the socket 46 is provided with a plurality of pogo pins 48 lengthwise through the socket 46. The technical features and relating structures of the test board 40 including the test substrate 41 and ZIF connectors 43 are the same as described in the first embodiment.

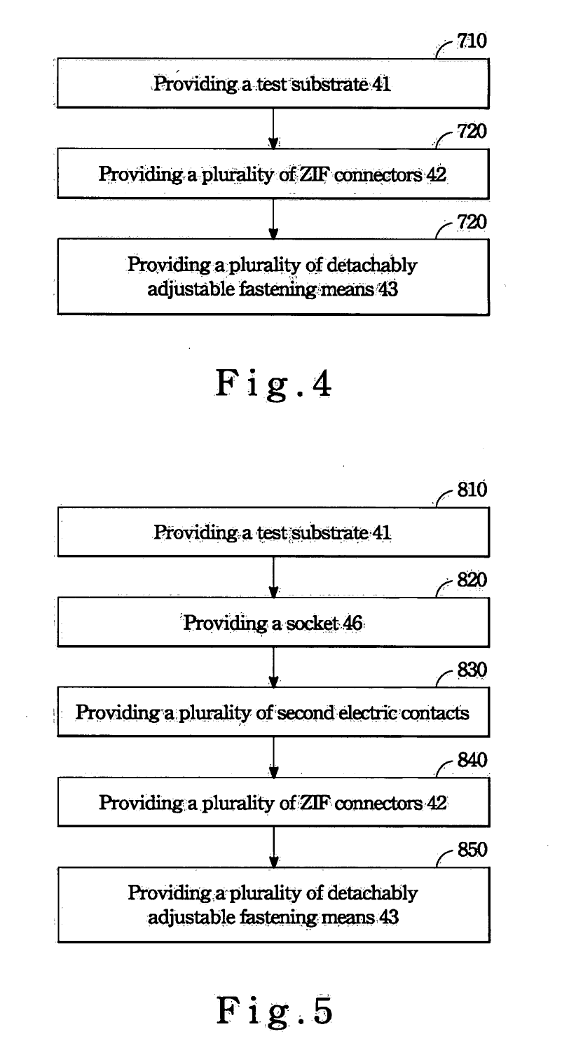

Refer to FIG. 4. An assembling method for the test board with the ZIF connectors and is shown in accordance with the third preferable embodiment of the present invention. The assembling method 700 includes the following steps:

(1) provide a test substrate 41 (step 710) having a first surface 411, a second surface 412, and a plurality of first through-holes 413 perpendicular to the first surface 411 and the second surface 412 of the test substrate 41. Pairs of first electric contacts (not shown) are provided on the first surface 411 adjacent to both sides of the first through-holes 413. Alternatively, a plurality of second electric contacts (not shown) are provided on the second surface 412 of the test substrate 41 and electrically contacted with the first electric contacts;

(2) provide a plurality of ZIF connectors 42 (step 720), wherein the ZIF connectors 42 are arranged on the first surface 411 of the test substrate 41, and each of the plurality of ZIF connectors 42 has a plurality of parallel second through-holes 412 from the top to the bottom of the ZIF connectors 42 and pairs of electric terminals (not shown) are deposed on the bottom of each ZIF connector 42 for contacting the first electric contacts (not shown) of the test substrate 41; and

(3) provide a plurality of detachable and detachably adjustable fastening means 43 (step 730), passing through the first through-holes 413 and the second through-holes 421 so as to affix the ZIF connectors 42 on the first surface 411 of the test substrate 41.

In the assembling method of the above mentioned embodiment, the fastening means 43 is detachably adjustable and it is a combination of a bolt 431 and a nut 432. For the sake of convenient assembly, the bolt 431 may pass through the test substrate 41 and the ZIF connector 42 upon the test substrate 41 to affix the nut 432 on bottom of the ZIF connector 42, as shown in FIG. 2A. Alternatively, the bolt 431 may pass through the ZIF connector 42 and the test substrate 41 from the downside of the ZIF connector 42 so as to affix the nut 432 on the upside of the test substrate 41 (not shown). The number of the bolt 431 is not limited as long as the force to affix the ZIF connector 42 to the test substrate 41 is strong enough to make a stable connection.

In the above mentioned embodiment, multiple nuts can be integrated into a fastening plate 433 provided with multiple holes, as shown in FIG. 2B. When assembled, the bolt 431 may pass through the test substrate 41 and the ZIF connector 42 upon the test substrate 41 so as to affix the fastening plate 433 on the downside of the ZIF connector 42. Alternatively, the bolt 431 may pass through the ZIF connector 42 and the test substrate 41 under the ZIF connector 42 so as to affix the fastening plate 433 on the upside of the test substrate 41.

In the above mentioned embodiment, in order to enhance the fastening force to affix the ZIF connector 42 to the test substrate 41, the sealing get or resin may be further provided in the cross locking portions of the fastening means 43 to decrease the loosening possibility of the fastening means 43 for connecting the ZIF connector 42 with the test substrate 41.

In the above mentioned embodiment, the first depressor 44 may be further provided on the top surface of the ZIF connectors 42, as shown in FIG. 2C. The first depressor 44 is provided with the third through-holes 441 located on the opposite side of the second through-holes 421 so that the fastening means 43 can pass therethrough for being affixed thereon. The function of the first depressor 44 is to scatter the pressure directly applied on the ZIF connectors 42 from the fastening means 43 as well as to prevent the fastening means 43 from scratching the surface of the ZIF connector 42.

In the above mentioned embodiment, the second depressor 45 may be provided on the second surface 412 of the test substrate 41, as shown in FIG. 2D. The second depressor 45 is provided with the fourth through-holes 451 located on the opposite side of the first through-holes 413 of the test substrate 41 so that the fastening means 43 can pass therethrough for being affixed thereon. The function of the second depressor 45 is to scatter the pressure directly applied on the test substrate 41 from the fastening means 43 as well as to prevent the fastening means 43 from scratching the surface of the test substrate 41.

The above mentioned first depressor 44 and second depressor 45 may be provided separately or together. The fastening means 43 may be a combination of a bolt 431 and a nut 432, or a combination of a bolt 431 and a fastening plate 433. When assembled, a bolt 431 may pass through the test substrate 41 and the ZIF connectors 42 from the upside of the test substrate 41 for being affixed on the bottom of the ZIF connectors 42; alternatively, a bolt 431 may pass through the ZIF connectors 42 and the test substrate 41 from the downside of the ZIF connectors 42 for being affixed on the upside of the test substrate 41.

In the above mentioned embodiment, wherein a plurality of the ZIF connectors 42 are arranged in an array shape, as shown in FIG. 2E, in four sides of rectangular shape, in opposite sides shape or in adjacent sides shape of the rectangular.

Refer to FIG. 5. A method 800 of fabricating a test board with ZIF connectors is shown in accordance with the fourth preferable embodiment of the present invention, comprising the steps of:

(1) providing a test substrate 41 (step 810), wherein the test substrate 41 has a first surface 411, a second surface 412, and a plurality of first through-holes 413 through the first surface 411 and the second surface 412. Pairs of the first electric contacts 413 (not shown) are disposed on both sides of the first through-holes 413 of the first surface 411;

(2) providing at least a socket 46 (step 820), wherein the socket 46 is affixed on the second surface 412 of the test board 41 for receiving an integrated circuit device under test 47, and a plurality of pogo pins 48 are provided lengthwisely through the socket 46;

(3) providing a plurality of second electric contacts (step 830), wherein the plurality of second electric contacts provided on the second surface 412 of the test substrate 41 are not only electrically contacted with the pogo pins 48 of the socket 46 but electrically connected to the first electric contacts on the first surface 411 of the test board 41;

(4) providing a plurality of ZIF connectors 42 (step 840), wherein the plurality of ZIF connectors are arranged on the first surface 411 of the test substrate 41, and each of the plurality of ZIF connectors 42 has a plurality of second through-holes 421 parallelly arranged through the ZIF connectors, and pairs of electric terminals (not shown) are deposed on the bottom of each ZIF connector 42 for contacting the first electric contacts (not shown) of the test substrate 41; and

(5) providing a plurality of detachably adjustable fastening means 43 (step 850), wherein the plurality of detachably adjustable fastening means 43 are disposed through the first through-holes 413 and the second through-holes 421 for assembling and disassembling the ZIF connectors 42 on the first surface 411 of the test substrate 41.

In the assembling method of the above mentioned embodiment, the technical features and relating structures of the above elements such as the test substrate 41, the socket 46, the second electric contact, the ZIF connector 42 and the detachably adjustable fastening means 43 are the same as described in the third embodiment.

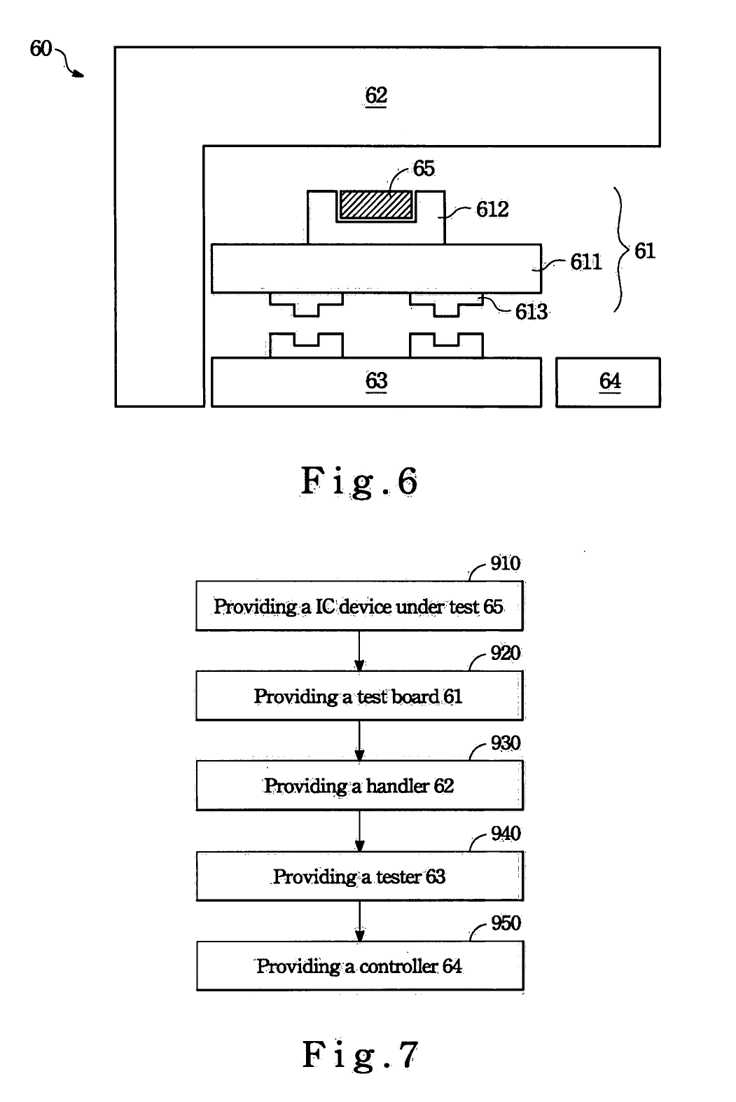

Refer to FIG. 6. An IC device test system is shown in accordance with the fifth preferable embodiment of the present invention. The IC device test system 60 comprises a test board 61, a handler 62, a tester 63 and a controller 64. The test board 61 comprises a test substrate 611, at least a socket 612, a plurality of second electric contacts (not shown), a plurality of ZIF connectors 613 and a plurality of detachably adjustable fastening means (not shown). And, a gap (not shown) exists between the test substrate 611 and the ZIF connector 613 for adjusting contact force between the test substrate 611 and the ZIF connector 613 by means of a plurality of the detached adjustable fastening means (not shown). Wherein, a handier 62 includes a plurality of trays and loads the IC devices 65 under test onto the trays on the test board 61 for testing. A controller 64 connects to the plurality of ZIF connectors 613 and a tester 63 for sending calculated test results back to the handler 62. The handler 62 classifies the tested IC devices in accordance with the testing results. The technical features and relating structures of the test board 61 are the same as described in the second embodiment.

Refer to FIG. 7. An IC device test method is illustrated in accordance with the sixth preferable embodiment of the present invention. The IC device test method includes the following steps:

(1) provide an integrated circuit device under test 65 (step 910);

(2) provide a test board 61 (step 920) so as to load the IC device under test 65 for performing a final test. The test board 61 includes at least a test board 611, at least a socket 612, a plurality of ZIF connectors 613, a plurality of second electrical pads (not shown) and a plurality of detachably adjustable fastening means (not shown). Wherein, the technical features and relating structures of the test board 61 are the same as described in the second preferable embodiment;

(3) provide a handler 62 (step 930), wherein the handler 62 comprises a plurality of cartridges for loading the integrated circuit devices onto the test board for testing so as to generate an IC sorting based on test results of the IC devices;

(4) provide a tester 63 (step 940), wherein the tester 63 has a ZIF female plug connector so as to correspondingly connect to the plurality of ZIF connectors 613 for sending test results back to the handler 62; and

(5) provide a controller 64 (step 950) for receiving the test signals from the tester 63, processing the testing signals, and sending the calculated test results to a controlling and processing means 68 from the tester 63 so as to output the test results.

The above mentioned preferred embodiments of the present invention are not meant to limit the scope of the present invention. The description of the present invention should be understood by those skilled in the art. Moreover, any changes or modifications or the equivalent thereof that can be made without departing from spirit of the present invention should be protected by the following claims.

1. A test board with ZIF connectors, comprising:
a test substrate having a first surface, a second surface, a plurality of first through-holes, the plurality of first through-holes being perpendicular to the first surface and the second surface of said test substrate,
a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
a plurality of detachably adjustable fastening means being disposed through the first through-holes and the second through-holes for assembling and disassembling said ZIF connectors on the first surface of said test substrate.

2. The test board of claim 1, further comprising a plurality of first depressors on the top surface of said ZIF connectors, wherein a plurality of third through-holes are provided on an opposite side of the second through-holes so that the detachably adjustable fastening means may pass therethrough for being affixed thereon.

3. The test board of claim 1, further comprising a plurality of second depressors on the second surface of said test substrate, wherein a plurality of fourth through-holes are provided on an opposite side of the first through-holes so that the detachably adjustable fastening means may pass therethrough for being affixed thereon.

4. The test board of claim 1, wherein the plurality of detachably adjustable fastening means comprise a combination of bolts and nuts.

5. The test board of claim 1, wherein the plurality of detachably adjustable fastening means comprise bolts and fasten plates with multiple holes for fastening the bolts thereon.

6. The test board of claim 1, wherein the plurality of detachably adjustable fastening means are fastened adjacent on the second surface of the test substrate.

7. The test board of claim 1, wherein the plurality of detachably adjustable fastening means are fastened adjacent on the bottom side of the ZIF connectors.

8. The test board of claim 1, wherein a sealing gel or resin is further provided in a portion on which the detachably adjustable fastening means are fastened.

9. The test board of claim 1, wherein the plurality of the ZIF connectors are arranged in an array shape.

10. A test board with ZIF connectors, comprising:
a test substrate having a first surface, a second surface, a plurality of first through-holes, the plurality of first through-holes being perpendicular to the first surface and the second surface of said test substrate;
at least a socket being affixed on the second surface of said test board for receiving an integrated circuit device under test, said socket being provided with a plurality of pogo pins lengthwise through said socket;
a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
a plurality of detachably adjustable fastening means being disposed through the first through-holes and the second through-holes for assembling and disassembling said ZIF connectors on the first surface of said test substrate.

11. A method of fabricating a test board with ZIF connectors and, comprising the steps of:
providing a test substrate having a first surface, a second surface, a plurality of first through-holes, the plurality of first through-holes being perpendicular to the first surface and the second surface of said test substrate;
providing a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
providing a plurality of detachably adjustable fastening means being disposed through the first through-holes and the second through-holes for assembling and disassembling said ZIF connectors on the first surface of said test substrate.

12. A method of fabricating a test board with ZIF connectors and, comprising the steps of:
providing a test substrate having a first surface, a second surface, a plurality of first through-holes, the plurality of first through-holes being perpendicular to the first surface and the second surface of said test substrate;
providing at least a socket being affixed on the second surface of said test board for receiving an integrated circuit device under test, said socket being provided with a plurality of pogo pins lengthwise through said socket;
providing a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
providing a plurality of detachably adjustable fastening means being disposed through the first through-holes and the second through-holes for assembling and disassembling said ZIF connectors on the first surface of said test substrate.

13. An IC device test system, comprising:
a test board comprising:
a test substrate having a first surface, a second surface, a plurality of first through-holes, the plurality of first through-holes being perpendicular to the first surface and the second surface of said test substrate;
at least a socket being affixed on the second surface of said test board for receiving an integrated circuit device under test, said socket being provided with a plurality of pogo pins lengthwise through said socket;
a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
a plurality of detachably adjustable fastening means being disposed through the first through-holes and the second through-holes for assembling and disassembling said ZIF connectors on the first surface of said test substrate;
a handler for receiving IC devices under test and placing the IC devices under test on said test board, and classifying in accordance with testing result of said IC devices after test;
a tester with female plugs for connecting the plurality of corresponding ZIF connectors; and
a controller for sending, receiving and processing a test signal of said tester.

14. An IC device test method, comprising the steps of:
providing an integrated circuit device under test;
providing a test board, which comprises:
a test substrate having a first surface, a second surface, a plurality of first through-holes, the plurality of first through-holes being perpendicular to the first surface and the second surface of said test substrate;
at least a socket being affixed on the second surface of said test board for receiving the integrated circuit device under test, said socket being provided with a plurality of pogo pins lengthwise through said socket;
a plurality of ZIF connectors being arranged on the first surface of said test board, each of said plurality of ZIF connectors having a plurality of second through-holes parallelly arranged through said ZIF connectors, and pairs of electric terminals being deposed on the bottom of each ZIF connector for contacting said test substrate; and
a plurality of detachably adjustable fastening means being disposed through the first through-holes and the second through-holes for assembling and disassembling said ZIF connectors on the first surface of said test substrate;
providing a handler for loading the IC devices under test onto said test board for testing so as to generate an IC sorting based on test results of the IC devices;
providing a tester with female plugs for connecting the plurality of corresponding ZIF connectors; and
providing a controller for sending, receiving and processing test signals from said tester.
